(19) United States
(12) Patent Application Publication
(10) Pub. No.: US 2025/0266261 A1
(43) Pub. Date: Aug. 21, 2025

(54) METHODS OF FORMING SEMICONDUCTOR WAFERS WITH BACKSIDE STOP PINS, AND ASSEMBLIES RESULTING FROM SUCH METHODS

(71) Applicant: Micron Technology, Inc., Boise, ID (US)

(72) Inventor: Andrew T. McDonald, Boise, ID (US)

(21) Appl. No.: 19/015,505

(22) Filed: Jan. 9, 2025

Related U.S. Application Data
(60) Provisional application No. 63/554,508, filed on Feb. 16, 2024.

(51) Int. Cl. H01L 21/304; H01L 21/02; H01L 21/306; H01L 21/768; H01L 21/78; H01L 23/48

(52) U.S. Cl. CPC H01L 21/304; H01L 21/02282; H01L 21/306; H01L 21/76898; H01L 21/78; H01L 23/481

(57) ABSTRACT

A method of forming a semiconductor wafer is provided. The method includes providing a wafer with an upper surface and a back surface, patterning a backside stop pattern on the upper surface, etching backside stop pins and wafer-bond vias in the upper surface of the wafer, wherein the pins are placed according to the backside stop pattern, and wherein the pins have a depth that is greater than a depth of the wafer-bond vias, filling the backside stop pins with a stopping material, polishing the upper surface to remove excess stopping material, polishing the back surface at a first speed until contacting the backside stop pins; and polishing the back surface at a second speed until contacting the wafer-bond vias, wherein the second speed is slower than the first speed.

### CROSS-REFERENCE TO RELATED APPLICATION(S)

The present application claims priority to U.S. Provisional Patent Application No. 63/554,508, filed Feb. 16, 2024, the disclosure of which is incorporated herein by reference in its entirety.

### TECHNICAL FIELD

The present disclosure generally relates to semiconductor wafers, and more particularly relates to methods of forming semiconductor wafers with backside stop pins, and assemblies resulting from such methods.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts that transmit supply voltage, signals, etc., to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIGS. 1A, 1B, and 1C are a sequence of simplified schematic partial cross-sectional views illustrating a series of fabrication steps of an example semiconductor wafer.

FIGS. 2A, 2B, and 2C are a sequence of simplified schematic partial cross-sectional views illustrating a method of forming a semiconductor wafer in accordance with embodiments of the present technology.

FIG. 3 is a simplified schematic plan view with increasingly detailed views of a semiconductor wafer in accordance with embodiments of the present technology.

FIG. 4 is a simplified schematic cross-sectional view of a stack of semiconductor devices, with a detailed view of a semiconductor device, both in accordance with embodiments of the present technology.

FIG. 5 is a schematic view showing a system that includes a semiconductor device assembly configured in accordance with an embodiment of the present technology.

FIG. 6 is a flow chart illustrating a method of making a semiconductor device assembly in accordance with an embodiment of the present technology.

### DETAILED DESCRIPTION

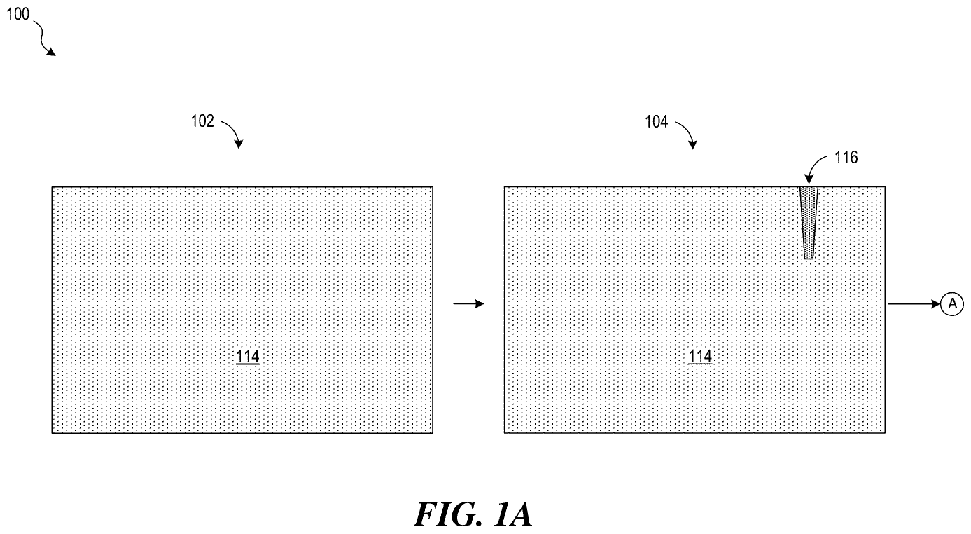

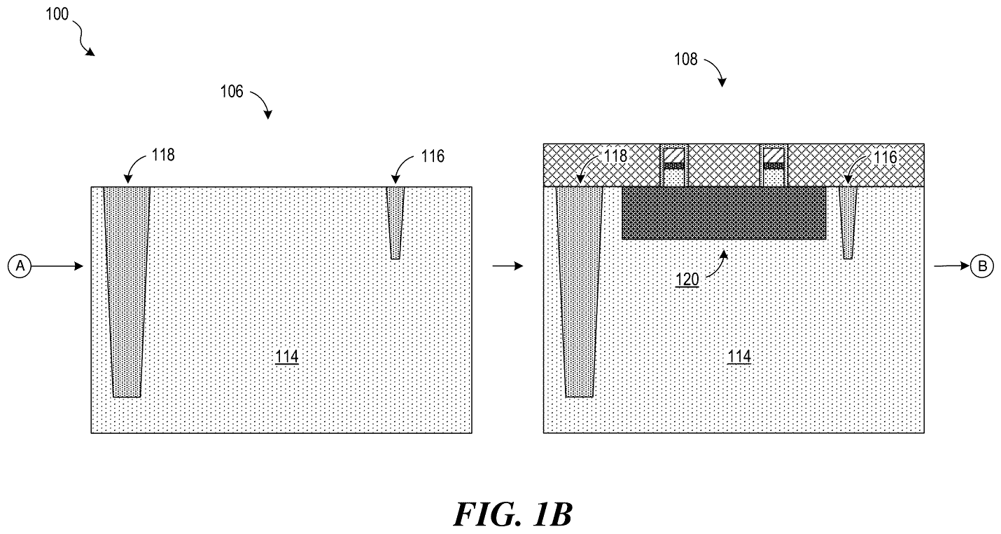

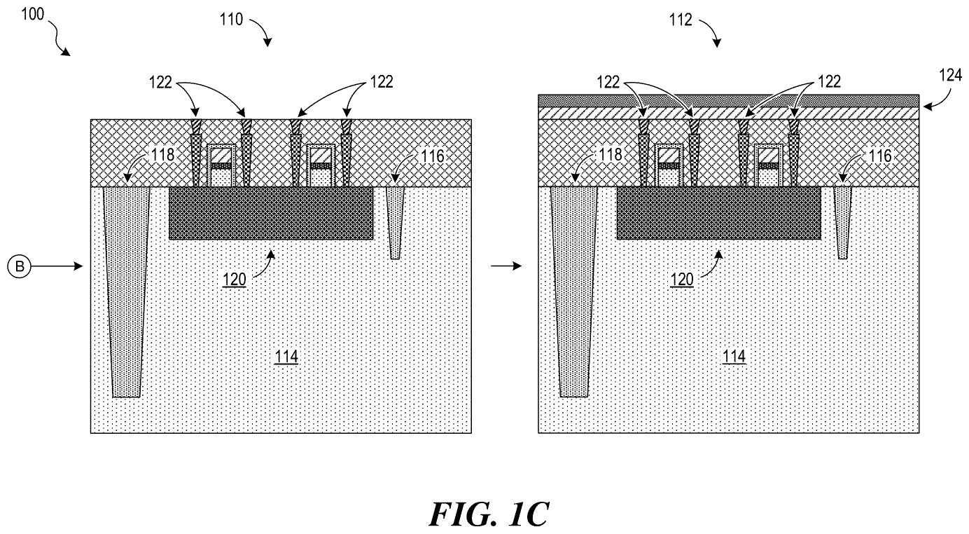

The electronics industry relies upon continuous innovation in the field of semiconductor packaging to meet the global need for higher-functioning technology. This demand calls for increasingly complicated assemblies of semiconductor devices, which may diverge in terms of plan area, thickness, connection methodology, etc. One approach to accommodate the packaging of such varied devices into a single assembly is to form semiconductor wafers of varying thicknesses, and then dice these wafers into singulated semiconductor devices. An example of one such approach is illustrated in FIGS. 1A, 1B, and 1C as a sequence of simplified schematic partial cross-sectional views illustrating a series of fabrication steps 100 of an example semiconductor wafer. In a first step 102, a silicon wafer 114 is provided. In a second step 104, shallow trenches 116 are etched into an upper surface of the wafer 114 and then filled with a dielectric material. Sockets and through-silicon vias (TSVs) 118 are formed in the upper surface of the wafer 114 in a third step 106. In a fourth step 108, gates 120 are formed and implanted on the upper surface. In a fifth step 110, contacts 122 are formed atop the gates 120. In a sixth step 112, a nitride and oxide cap 124 is disposed atop the contacts 122 to prepare the wafer 114 for bonding (e.g., to a chip or to another wafer).

One of the challenges in forming the wafer 114 in this manner, however, is Total Thickness Variation (TTV). TTV is a measure of the variation in thickness across the wafer 114. The greater the TTV, the lower the yield of viable semiconductor die from the wafer 114. A previous method for reducing TTV was Chemical-Mechanical Planarization (CMP). CMP is a process for polishing a surface to a uniform thickness by pressing that surface against a rotating pad of rigid micro-porous material that contains a mix of chemicals and abrasives. As part of the series of fabrication steps 100, CMP can be applied following the second step 104, the third step 106, and/or the sixth step 112, in order to produce a level surface.

In this series of steps 100, however, CMP is applied to the upper surface of the wafer 114. This enables CMP to stop at a point near the interface between an upper layer (e.g., of conductive material) and a lower layer (e.g., of dielectric material). This point is called the ‘stopping point’ because it is where the CMP process ends, due to the differing thicknesses between layers causing the CMP process to slow dramatically in the transition from one layer to the next. In certain cases, however, such as the case of a wafer-to-wafer bond, or a chip-to-wafer bond, the top surface of the wafer cannot be subjected to CMP. In these cases, and other cases, TTV remains a problem, especially as silicon wafers are thinned to less than 10 μm, 5 μm, 3 μm, 2 μm, or 1 even μm. Rather than employing more expensive or time-consuming solutions, one method of solving this problem is to apply CMP to the back of the wafer 114.

Applying CMP to the back of the wafer 114, however, creates additional problems. The ‘stopping point’ is not reached when CMP is applied to the bottom of the wafer 114. From this approach, once the CMP process reaches the interface between layers, it has already begun to impinge on sensitive electronics, e.g., the gates 120. The die, then, has been ruined.

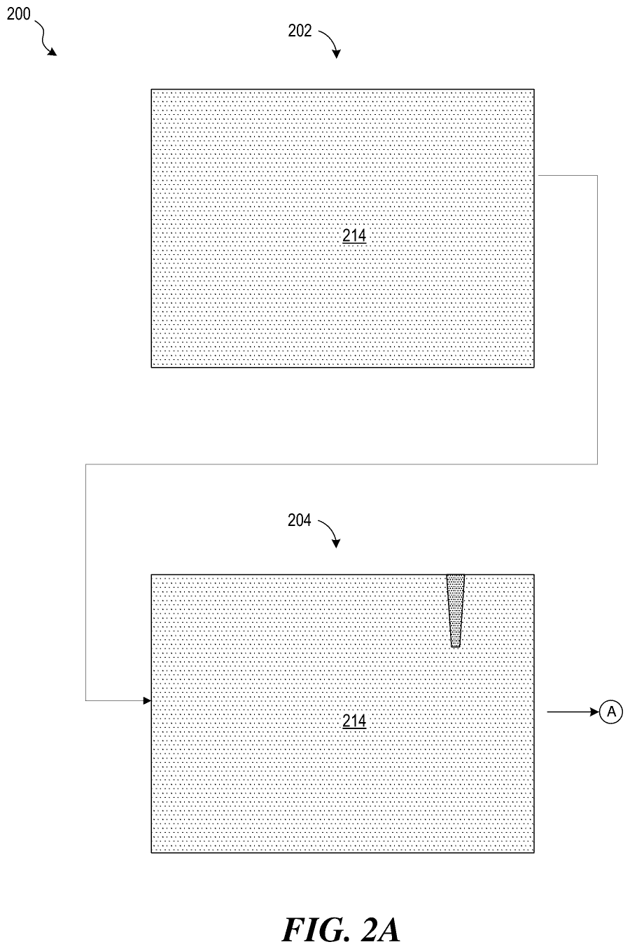

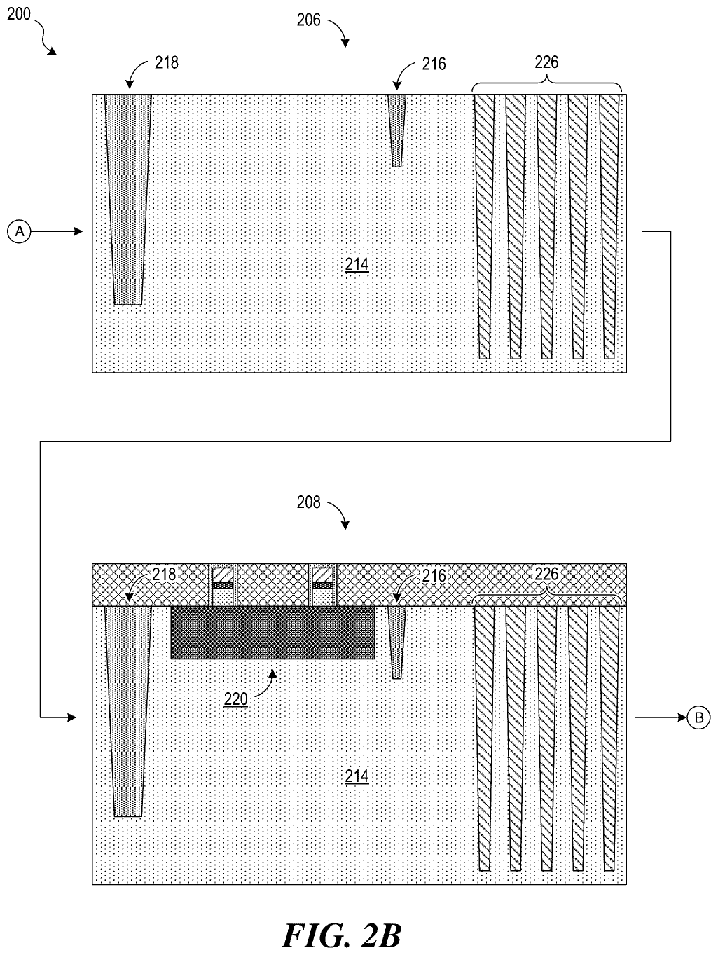

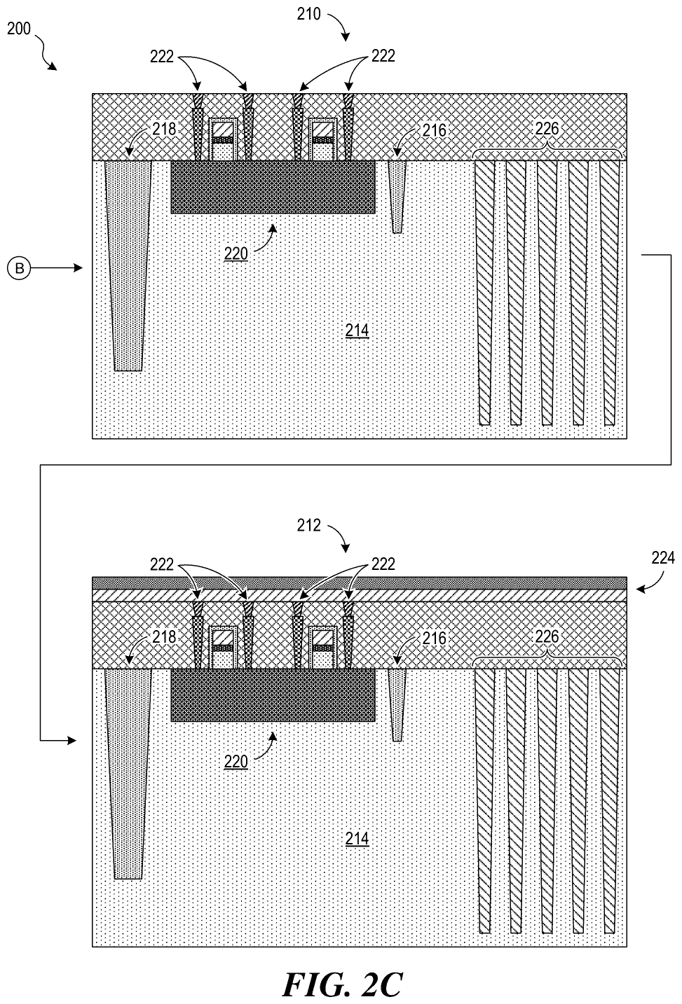

To address these drawbacks and others, various embodiments of the present disclosure provide methods of forming semiconductor wafers with backside stop pins, and assemblies resulting from such methods. FIGS. 2A, 2B, and 2C are a sequence of simplified schematic partial cross-sectional views illustrating a method 200 of forming a semiconductor wafer in accordance with embodiments of the present technology. The method 200 includes a first step 202, which can include providing a wafer 214 with an upper surface and a back surface. In certain embodiments, the wafer 214 can be at least greater than 100 μm, 300 μm, 500 μm, or even 700 μm thick. In certain embodiments, the upper surface can be an active or functional side of the wafer. In certain embodiments, the wafer 214 can be a CMOS wafer. The method includes patterning a backside stop pattern on the upper surface (e.g., via a photoresist patterning process). In some embodiments, the backside stop pattern can be distributed evenly on the upper surface of the wafer 214. In other embodiments, the backside stop pattern can be distributed more in an area in which the CMP progresses (e.g., removes material) more quickly. In some embodiments, the backside stop pattern can occupy up to 10%, 20%, 30%, 40%, or even 50% of the upper surface of the wafer 214. Alternatively, the upper surface can include a scribe line demarcating die, the scribe line including a scribe mark area; the backside stop pattern can be patterned inside this scribe line and outside the scribe mark area. Within each die area can be areas for banks. In such embodiments, the backside stop pattern can be patterned inside the die area and outside the banks' areas. Additionally, each bank area can include cells. In these embodiments, the backside stop pattern can be patterned inside the bank area and outside of the cells.

As illustrated, the method 200 can also include a second step 204, which can include etching shallow trenches 216 into the upper surface of the wafer 214 and then filling them with a dielectric material. In a third step 206, the method 200 includes etching backside stop pins 226 and wafer-bond vias 218 in the upper surface of the wafer 214. The backside stop pins 226 can alternatively or additionally be referred to as etch-stop pins. The etch-stop pins can each include a tapered region of non-conductive stopping material. The etch-stop pins can include a mechanically-altered bottom surface at a back surface of a substrate (e.g., the wafer 214, or a device). The backside stop pins 226 can be placed according to the backside stop pattern. Additionally, each backside stop pin can have a width or an opening that measures up to 10%, 20%, 30%, or an even larger proportion of the pin depth, or pin height. The depth can be equivalent to a predefined desired thickness of the wafer 214. The etch-stop pins can extend completely through a substrate (e.g., the wafer 214). To facilitate stopping the CMP progress prior to removing an undesirable amount of the wafer-bond vias 218, the backside stop pins 226 may have a depth that is greater than a depth of the wafer-bond vias 218. For example, in some embodiments, the depth of the backside stop pins measures at least 105%, 110%, 115%, 120%, or even more of the depth of the wafer-bond vias. Additionally, or alternatively, the backside stop pins 226 can have a tapered shape with a top end at the upper surface of the wafer 214 that is wider than a bottom end at a back surface of the wafer 214. The third step 206 can include filling the backside stop pins 226 with a stopping material (e.g., boron carbide (B₄C), diamond, white corundum (Al₂O₃), and/or silica (SiO₂). In some implementations, filling the backside stop pins can include depositing a second layer atop the first layer, the second layer including a high density plasma (HDP) oxide configured to offset film stress within the wafer and prevent cracking. Alternatively, or additionally, filling the backside stop pins further comprises spin-coating a third layer atop the second layer, the third layer comprising a spin-on dielectric (SOD) configured to facilitate planarization. In certain implementations, the stopping material can include a first layer of nitride or oxide, a second layer of HDP oxide disposed atop the first layer, and a third layer of SOD disposed atop the second layer. The third step 206 can also include polishing the upper surface of the wafer 214 to remove excess stopping material. Polishing the upper surface can include bonding the upper surface of the wafer to a carrier wafer. Etching the backside stop pins can further include tapering the backside stop pins such that the stopping material fills the pins without forming voids.

In a fourth step 208, gates 220 can be formed and implanted on the upper surface. In a fifth step 210, contacts 222 can be formed atop the gates 220. In a sixth step 212, a nitride and oxide cap 224 can be disposed atop the contacts 222 to prepare the wafer 214 for bonding (e.g., to a chip or to another wafer). The method 200 includes proceeding to polish the back surface of the wafer 214 at a first speed until contacting the backside stop pins 226. Due to the presence of the stopping material in the backside stop pins 226, the CMP process slows considerably during removal of the stopping material. The method 200 then includes polishing the back surface at a second speed until exposing the wafer-bond vias 218. The second speed for CMP can be slower than the first speed. In alternative embodiments, the second speed can measure less than or equal to 50% of the first speed (or, in other embodiments, less than 75%, less than 67%, less than 33%, etc.). Polishing the back surface can further include achieving a final wafer thickness with a desired Total Thickness Variation (TTV). The final wafer thickness can measure less than two microns (or, in other embodiments, less than 1.5 microns, 1.0 microns, 0.5 microns, etc.) and the desired TTV measures can measure plus or minus 0.25 microns (or, in other embodiments, plus or minus 0.2 microns, plus or minus 0.1 microns, plus or minus 0.05 microns, etc.).

The wafer can be a first wafer 214, and the method 200 can further include removing the carrier wafer. In such implementations, the first wafer 214 can be bonded to a second wafer by connecting the wafer-bond vias 218 to corresponding electrical contacts on the second wafer to form a wafer stack. The method can also include dicing the wafer stack to form a stack of semiconductor devices with backside stop pins 226.

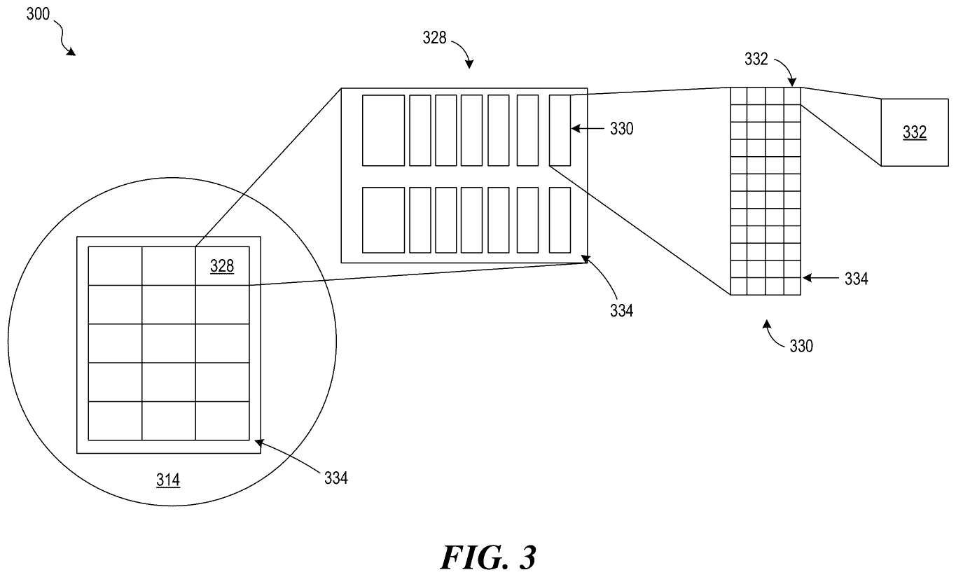

An example semiconductor wafer stack 300 formed by such methods is illustrated in FIG. 3, in accordance with embodiments of the present technology. The wafer stack 300 can include a first wafer 314 with an upper surface and features the same as those described in the wafer 214 above, illustrated in increasingly detailed views according to the Figure. In certain embodiments, the first wafer 214 can be a CMOS wafer. The first wafer 314 can have a backside stop pattern 334, in which the backside stop pattern 334 defines that area in which the backside stop pins can be etched. The backside stop pattern 334 can occupy up to twenty percent of the upper surface of the wafer 314. Alternatively, the upper surface can include a scribe line demarcating die 328, the scribe line including a scribe mark area (e.g., scribe regions between adjacent un-singulated die); the backside stop pattern 334 can be patterned inside this scribe line and outside the scribe mark area, as illustrated in FIG. 3. Within each die area 328 can be areas for banks 330. In such embodiments, the backside stop pattern 334 can be patterned inside the die area 328 and outside the banks' areas 330. Additionally, each bank area 330 can include cells 332. In some embodiments, the cells 332 can include active circuitry. In these embodiments, the backside stop pattern 334 can be patterned inside the bank area 330 and outside of the cells 332. In such embodiments, the bank area 330 can be a periphery region, and the backside stop pattern can be patterned inside the periphery region. Backside stop pins, or etch-stop pins, can be peripheral to active circuity of a semiconductor device. Each etch-stop pin can be spaced from a nearest etch-stop pin neighbor by at least fifty nanometers.

The first wafer 314 can be disposed on top of and electrically connected to a second wafer. The second wafer can include backside stop pins extending from an upper surface of the second wafer to a back surface, the backside stop pins comprising a stopping material. In some embodiments, the backside stop pins can have a tapered shape with a top end at the upper surface of the first and second wafers that is wider than a bottom end at the back surface of the first and second wafers. Additionally, or alternatively, the stopping material can include a first layer of nitride or oxide, a second layer of HDP oxide disposed atop the first layer, and a third layer of SOD disposed atop the second layer.

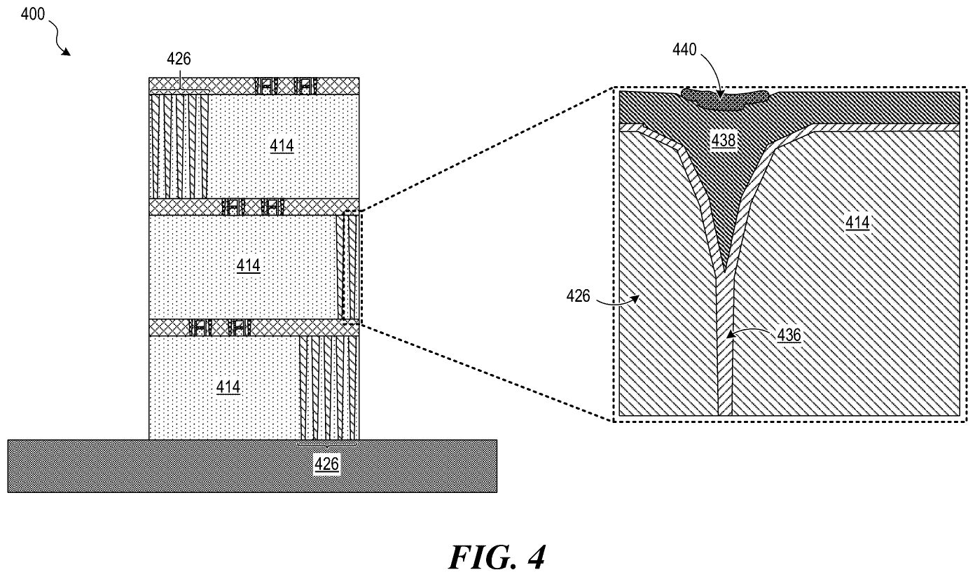

FIG. 4 is a simplified schematic cross-sectional view of a stack of semiconductor devices 400 in accordance with embodiments of the present technology. The stack 400 includes a device 414 with backside stop pins 426 filled with a stopping material. In some embodiment, the semiconductor devices 400 may be functionally identical devices (e.g., consequent of homogenous device stacking). In other embodiments, the semiconductor devices 400 may be different devices (e.g., consequent of heterogeneous stacking). Additionally, or alternatively, the stopping material can include a first layer 436, in isolation, or together with a second layer 438, and/or a third layer 440. The third layer 440 can include a spin-on dielectric (SOD) configured to facilitate planarization. The first layer 436 can include a nitride or an oxide. The second layer 438 can include an HDP oxide disposed atop the first layer 436, and configured to offset film stress within the wafer and prevent cracking. The third layer can include a SOD disposed atop the second layer 438, configured to facilitate planarization. As illustrated, in some embodiments, the backside stop pins 426 can have a tapered shape with a top end at the upper surface of the device 414 that is wider than a bottom end at the back surface of the device 414, and configured to prevent voids from forming within the stopping material. The backside stop pins 426 traverse a depth of the device 414 and can be configured to avoid forming electrical contacts with any adjacent devices 414 in the stack 400. The device 400 can include banks, each bank comprising cells. The backside stop pins 426 can be disposed in an area around and outside of the banks, or around and outside of the cells. The width of the backside stop pins 426 can measure at least 2 microns. In such embodiments, the backside stop pins 426 can be disposed in a cluster, in which each pin in the cluster can be separated from a nearest pin 426 by a distance. The distance, in these embodiments, can measure at least 50 nm.

Although in the foregoing example embodiment semiconductor device assemblies have been illustrated and described as including a single semiconductor device, in other embodiments assemblies can be provided with additional semiconductor devices. For example, the single semiconductor devices illustrated in FIGS. 2A-4 could be replaced with, e.g., a vertical stack of semiconductor devices, a plurality of semiconductor devices, mutatis mutandis.

In accordance with one aspect of the present disclosure, the semiconductor devices illustrated in the assemblies of FIGS. 2A-4 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

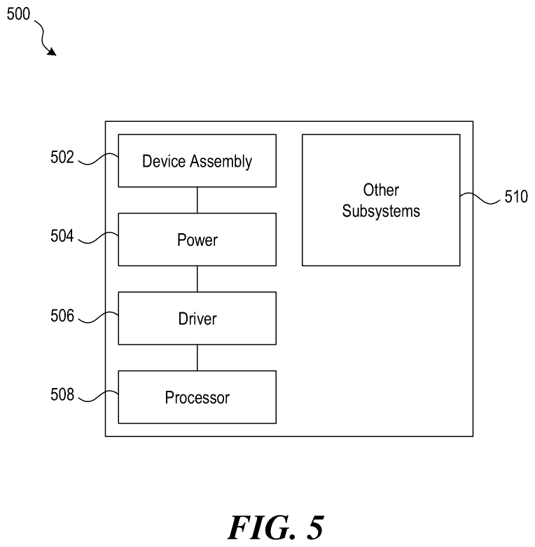

Any one of the semiconductor devices and semiconductor device assemblies described above with reference to FIGS. 2A-4 can be incorporated into any of a myriad of larger and/or more complex systems, a representative example of which is system 500 shown schematically in FIG. 5. The system 500 can include a semiconductor device assembly (e.g., or a discrete semiconductor device) 502, a power source 504, a driver 506, a processor 508, and/or other subsystems or components 510. The semiconductor device assembly 502 can include features generally similar to those of the semiconductor devices described above with reference to FIGS. 2A-4. The resulting system 500 can perform any of a wide variety of functions, such as memory storage, data processing, and/or other suitable functions. Accordingly, representative systems 500 can include, without limitation, hand-held devices (e.g., mobile phones, tablets, digital readers, and digital audio players), computers, vehicles, appliances and other products. Components of the system 500 may be housed in a single unit or distributed over multiple, interconnected units (e.g., through a communications network). The components of the system 500 can also include remote devices and any of a wide variety of computer readable media.

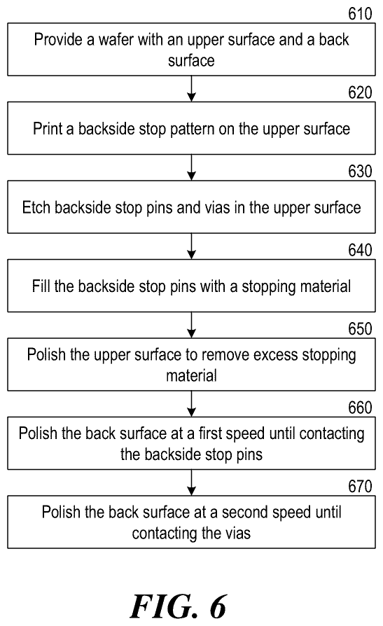

FIG. 6 is a flow chart illustrating a method of making a semiconductor wafer. The method includes providing a wafer with an upper surface and a back surface (box 610). The method also includes patterning a backside stop pattern on the upper surface (box 620). The method also includes etching backside stop pins and wafer-bond vias in the upper surface of the wafer. The pins are placed according to the backside stop pattern, and the pins have a depth that is greater than a depth of the wafer-bond vias (box 630). The method also includes filling the backside stop pins with a stopping material (box 640). The method also includes polishing the upper surface to remove excess stopping material (box 650). The method also includes polishing the back surface at a first speed until contacting the backside stop pins (box 660). The method also includes polishing the back surface at a second speed until contacting the wafer-bond vias. The second speed is slower than the first speed (box 670).

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A method of forming a semiconductor wafer with backside stop pins, the method comprising:
providing a wafer with an upper surface and a back surface;
patterning a backside stop pattern on the upper surface;
etching stop pin openings through the backside stop pattern in the upper surface of the wafer, and wherein the pin opening has a depth equivalent to a predefined desired thickness;
filling the stop pin openings with a stopping material;
polishing the back surface until the wafer is at the predefined desired thickness, wherein polishing the back surface proceeds at a first speed until slowed to a second speed by contact with the backside stop pins.

2. The method of claim 1, wherein the second speed is less than fifty percent of the first speed.

3. The method of claim 1, wherein the backside stop pattern occupies up to twenty percent of the upper surface of the wafer.

4. The method of claim 1, wherein each stop pin opening has a width that is less than or equal to 20% of the pin depth.

5. The method of claim 1, wherein polishing the back surface at a second speed further comprises:
thinning the wafer to a thickness of less than 2.0 μm with a total thickness variation (TTV) of less than ±0.25 μm.

6. The method of claim 1, wherein the depth of the stop pin openings is at least 10% greater than the depth of TSVs disposed in the wafer.

7. The method of claim 1, wherein the stopping material comprises a first layer including a nitride or an oxide, and wherein etching the stop pin openings further comprises tapering the stop pin openings such that the stopping material fills the pins without forming voids.

8. The method of claim 7, wherein filling the stop pins openings further comprises depositing a second layer over the first layer, the second layer including a high density plasma (HDP) oxide.

9. The method of claim 8, wherein filling the stop pin openings further comprises spin-coating a third layer above the second layer, the third layer comprising a spin-on dielectric (SOD).

10. The method of claim 1, wherein the wafer is a CMOS wafer.

11. The method of claim 1, wherein the wafer includes scribe regions between adjacent un-singulated dies, and wherein the backside stop pattern is patterned inside a scribe line and outside a scribe mark area.

12. The method of claim 11, wherein each die comprises active circuitry and a periphery region, and wherein the backside stop pattern is patterned inside the periphery region.

13. A semiconductor device, comprising:
a silicon substrate;
one or more through-silicon vias (TSVs) extending completely through the substrate;
a plurality of etch-stop pins extending completely through the substrate, the etch-stop pins each comprising a tapered region of non-conductive stopping material.

14. The semiconductor device of claim 13, wherein the stopping material comprises a first layer of nitride or oxide and a second layer of HDP oxide disposed over the first layer.

15. The semiconductor device of claim 13, wherein the etch-stop pins taper from a first width at an active surface of the device to a second width less than the first width at a back surface of the device.

16. The semiconductor device of claim 15, wherein the etch-stop pins include a mechanically-altered bottom surface at the back surface of the device.

17. The semiconductor device of claim 15, wherein the second width is less than 20% of a height of the etch-stop pins.

18. The semiconductor device of claim 13, wherein the etch-stop pins are all peripheral to active circuitry of the semiconductor device.

19. The semiconductor device of claim 13, wherein each etch-stop pin is spaced from a nearest etch-stop pin neighbor by at least 50 nm.

20. A method of forming a semiconductor wafer with backside stop pins, the method comprising:
providing a wafer with an upper surface and a back surface;
forming through-silicon vias (TSVs) in the wafer;
patterning a backside stop pattern on the upper surface;
etching stop pin openings through the backside stop pattern in the upper surface of the wafer, and wherein the pin openings have a first depth that is greater than a second depth of the TSVs;
filling the stop pin openings with a stopping material;
polishing the back surface at a first speed until contacting the backside stop pins; and
polishing the back surface at a second speed until contacting the TSVs, wherein the second speed is slower than the first speed.
